(19) United States
(12) Patent Application Publication
(10) Pub. No.: US 2016/0076142 A1
(43) Pub. Date: Mar. 17, 2016

(54) Deposition Apparatus and Deposition Method Using the Same

(71) Applicant: ADVANCED ION BEAM TECHNOLOGY, INC., Hsinchu (TW)

(72) Inventors: Tienyu SHENG, Saratoga, CA (US); Hao CHEN, Pleasanton, CA (US)

(21) Appl. No.: 14/952,624

(22) Filed: Nov. 25, 2015

Related U.S. Application Data
(63) Continuation-in-part of application No. 14/201,747, filed on Mar. 7, 2014.

(51) Int. Cl. C23C 14/48; C23C 14/30; H01L 21/265; C23C 14/22

(52) U.S. Cl. CPC C23C 14/48; C23C 14/221; C23C 14/30; H01L 21/265

(57) ABSTRACT

The present invention provides a deposition apparatus and deposition method using the same. The deposition apparatus comprises: a process chamber, wherein a work piece is disposed therein; a plasma source chamber coupled to the process chamber, the plasma source chamber comprising a first plasma generator for ionizing a first gas in the plasma source chamber to generate a first plasma having ions, the ions of the first plasma with ions bombard the work piece; and a second plasma generator disposed within the process chamber, the second plasma generator ionized a second gas in the process chamber to generate a second plasma having radical, the second plasma having radical deposits a surface of the work piece.

### CROSS-REFERENCE TO RELATED APPLICATION

This is a continuation-in-part of application Ser. No. 14/201,747, filed in Mar. 7, 2014.

### BACKGROUND OF THE INVENTION

1. Field of the Invention

The present invention is related to a deposition apparatus and deposition method using the same, in particular, to a deposition apparatus having a function of bombarding surface of a work piece by ions, and a deposition method using the deposition apparatus.

2. Description of the Prior Art

Thin film deposition is an important process used in semiconductor manufacturing. For example, thin film deposition may be used to deposit various materials, such as monocrystalline, polycrystalline, amorphous and epitaxial material, on work piece (e.g., semiconductor substrate) to form thin film. In conventional thin film deposition process, the adjustable process parameters include nothing else but vacuum degree, temperature of the process chamber or concentration of the deposition material; however, there is a limitation of the conventional to control the result of the film deposition.

In view of the problem as above, it is now a current goal to control the result of the film deposition, effectively.

### SUMMARY OF THE INVENTION

The present invention provides a deposition apparatus and a deposition method using the same. The deposition apparatus may provide an extra ion source to bombard the work piece by ions, so as to accelerate the thin film deposition and increase the controlled parameter of the thin film deposition process.

One of the embodiments of the present invention is a deposition apparatus, comprising: a process chamber, wherein a work piece is disposed therein; a plasma source chamber coupled to the process chamber, the plasma source chamber comprising a first plasma generator for ionizing a first gas in the plasma source chamber to generate a first plasma having ions, the ions of the first plasma bombard the work piece; and a second plasma generator disposed within the process chamber, the second plasma generator ionized a second gas in the process chamber to generate a second plasma having radical to deposit a surface of the work piece.

The other embodiment of the present invention is a deposition method, comprising the following steps: positioning a work piece in a process chamber, wherein the process chamber comprise a second plasma generator; operating a first plasma generator in a plasma source chamber to ionize a first gas in the plasma source chamber and then generate a first plasma having ions, the ions of the first plasma bombard the work piece, wherein the plasma source chamber coupled to the process chamber; and operating the second plasma generator to ionize a second gas in the process chamber, and then generate a second plasma having radical, the second plasma having radical deposits a surface of the work piece.

The purpose, technical content, characteristic and effect of the present invention will be easy to understand by reference to the following detailed descriptions, when taken in conjunction with the accompanying drawings and the particular embodiment.

### BRIEF DESCRIPTION OF THE DRAWINGS

FIG. 1 illustrates an exemplary deposition apparatus according to an embodiment of the present invention.

FIG. 2 illustrates a cross-sectional view of an exemplary plasma source chamber.

FIG. 3 illustrates a perspective view of an exemplary plasma source chamber.

### DESCRIPTION OF THE PREFERRED EMBODIMENT

The embodiments as above only illustrate the technical concepts and characteristics of the present invention; it is purposed for person ordinary skill in the art to understand and implement the present invention, but not for the limitation to claims of the present invention. That is, any equivalent change or modification in accordance with the spirit of the present invention should be covered by the appended claims.

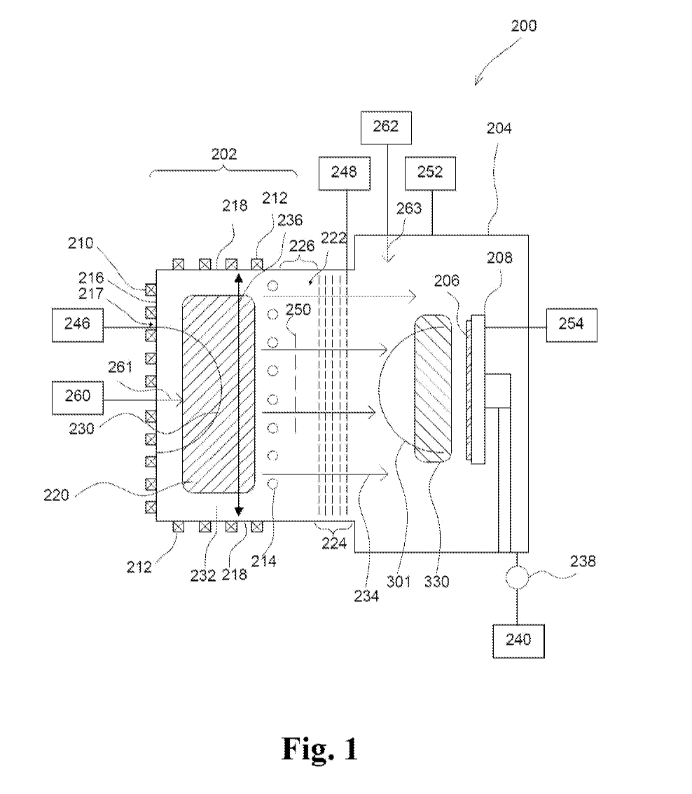

FIG. 1 depicts an exemplary deposition apparatus 200, comprises a process chamber 204 disposed a work piece 206 therein. The deposition apparatus 200 also comprises a plasma source chamber 202 coupled to the process chamber 204. The plasma source chamber 202 is configured to generate first plasma 220 having ions within plasma generation region 232 (the definition of the plasma generation region 232 will be described in the appended paragraph) by a first plasma generator 230 disposed in the plasma source chamber 220. The first plasma generator 230 is used to ionize a first gas 261 in the plasma source chamber 202 to generate a first plasma 220 having ions. In detail, the first plasma 220 may be generated by supplying a first gas 261 into plasma source chamber 202 and introducing power (e.g., electrical power or AC electric power) from power source (e.g., electrical power or AC electric power) into plasma source chamber 202 to ionize and dissociate the first gas 261.

In this example, plasma source chamber 202 is coupled to gas inlet 260 to supply the first gas 261 into plasma source chamber 202. Power source 246 is coupled to one or more first plasma generator 230 through an impedance matching network (not shown) to introduce LF, RF, or VHF power into plasma source chamber 202 via the one or more first plasma generator 230. The introduced LF, RF, or VHF power energizes electrons in plasma generation region 232, which in turn ionize and dissociate the first gas 261, thereby forming first plasma 220 in plasma generation region 232. First plasma generator 230 is disposed within plasma source chamber 202 and is configured to enable plasma 220 to be stably generated and sustained at pressures below 0.1 Pa without the use of an additive gas (e.g., hydrogen, argon, etc.).

In one embodiment, the first gas 261 may comprise atoms to be deposited on the surface of the work piece, for example, the first gas may comprise: AsH₃, PH₃, SiH₄, SiH₂(CL)₂, Si₂H₆, SiF₄, GeH₄, CH₃OH,O₂, N₂O, B₂H₆, Ar, Kr, Xe or NH₃. In the other embodiment, the first gas 261 may comprise atoms to be implanted on the surface of the work piece, for example, the first gas may comprise: AsH₃, PH₃, BF₃, H₂, N₂, O₂, He, Ar, Kr, Xe, N₂, CO₂, CO, CF₄ or CH₄.

The reaction in the plasma source chamber will be described. When the first gas accesses into the plasma source chamber, a first reaction, that is, dissociative ionization and electron impact ionization will be conducted. For example, in the case of the first gas is AsH₃, the first reaction are conducted as follows:

Dissociative Ionization

e+AsH₃→AsH₂⁺+H*+2e

e+AsH₃→AsH⁺+H₂+e

e+AsH₃→As⁺H₂+H*+2e

### Electron Impact Ionization:

e+AsH₃→AsH₃⁺+2e

As the result, the first gas is ionized and dissociated by the first plasma generator and generate excited electron, that is, the first plasma having ions. The ion beams of the first plasma will be extracted and accelerated toward the work piece in the process chamber by the grid to conduct implantation or to assist deposition.

Although in this example, plasma source chamber 202 is configured to supply LF, RF or VHF power through first plasma generator 230 to form first plasma 220, it should be recognized that other configurations may be possible to supply power into plasma source chamber 202. For example, first plasma generator 230 may comprise antennas or induction coils that are disposed in or around the outside of plasma source chamber 202. In another example, plasma source chamber 202 may be configured to supply UHF or microwave power into plasma source chamber 202 to form first plasma 220. In yet another example, plasma source chamber 202 may be configured to generate energetic thermionic electrons in plasma generation region 232 to form plasma 220. For example, a tungsten filament may be heated in plasma generation region 232 to generate energetic thermionic electrons.

The deposition apparatus 200 also comprises a second plasma generator 301 disposed in the process chamber 204 and an gas inlet 262 to access a third gas 263 into the process chamber 204. Wherein, the second plasma generator 301 may comprise antennas or induction coils that are disposed in or around the outside of process chamber 204, and the power of the second plasma generator may be different from that of the first plasma generator.

The second plasma generator 301 may ionize a second gas in the process chamber 204 to generate second plasma 330 having radical, herein, the second gas comprises ion beams 234 of the first plasma 220 and the third gas 263. Wherein, the ion beams 234 of the first plasma 220 may pass through the second plasma generator 301 and bombard the work piece 206, and the second plasma 330 having radical may deposit a surface of the work piece 206. In this case, the bombardment by the ion beams 234 on the work piece may facilitate the deposition of the second plasma, and therefore approve the deposition efficiency.

In one embodiment, the third gas 263 may comprise atoms to be deposited on the surface of the work piece, for example, the third gas may comprise: AsH₃, PH₃, SiH₄, SiH₂(CL)₂, Si₂H₆, SiF₄, GeH₄, CH₃OH,O₂, N₂O, B₂H₆, Ar, Kr, Xe or NH₃.

The reaction in the process chamber will be described. When the second gas accesses into the process chamber, that is, when the third gas and the ions access into the process chamber through the gas inlet and grids, respectively, a secondary reaction (ion-molecule or radical-molecule reaction and recombination of the radicals and ions) will be conducted. For example, in the case of the third gas is AsH₃, the secondary reaction are conducted as follows:

Ion-molecule or Radical-Molecule Reaction:

AsH₃⁺+AsH₃→AsH₂⁺+AsH₂*+H₂

AsH₂⁺+AsH₃→AsH₃⁺+AsH₂*

AsH⁺+AsH₃→AsH₂⁺+AsH₂*

AsH₃+H*→H₂+AsH₂*

### Recombination of the Radicals and Ions:

e+AsH₃→AsH₃

e+AsH₂⁺+H*→AsH₃

e+AsH⁺2H*→AsH₃

e+As⁺→As

e+As⁺+3H*→AsH₃

H*+AsH₂→AsH₃

H₂+AsH*→AsH₃

As the result, most of radicals (AsH₂*) are form by second plasma generator in the process chamber, and the radicals may react with the ions and hydrogen to deposit on the surface of the work piece.

Process chamber 204 may be coupled, via throttle valve 238, to high-speed vacuum pump 240. For example, high-speed vacuum pump 240 may be configured to pump at a rate of at least several hundred liters per second. Throttle valve 238 and high-speed vacuum pump 240 may be configured to maintain an operating pressure of below 0.1 Pa (and in some cases below 0.02 Pa) in plasma source chamber 202 and process chamber 204. Additionally, the deposition apparatus may include one or more cryo-panels disposed within process chamber. The one or more cryo-panels may serve to capture residual gases or organic vapors to achieve ultra-low operating pressures. In one example, the one or more cryo-panels may be configured to maintaining a pressure of below 0.02 Pa in plasma source chamber 202 and process chamber 204.

The deposition apparatus 200 in the present invention further comprises a plurality of grids 224 disposed between the first plasma generator 230 and a support structure 208 disposed with the process chamber 204. One or more grids of grids 224 may be coupled to one or more bias power sources 248 to apply a bias voltage to grids 224. Bias power source 248 may be, for example, a DC power source, a pulsed DC power source, an RF power source, or a combination thereof. In this example, grids 224 are configured to extract ion beam 234 from first plasma 220 and accelerate ion beam 234 to a desired energy level towards work piece 206.

Additionally, grids 224 may be configured to focus ion beam 234 and thus collimate ion beam 234. It should be recognized that grids 224 may be configured to extract multiple ion beamlets from plasma 220 and that ion beam 234 may thus comprise multiple ion beamlets. Furthermore, grids 224 may control the ion concentration distribution of the ion beam 234 of the first plasma 220.

As shown in FIG. 1, deposition apparatus 200 may optionally include absorber 250 for adjusting the current density profile of ion beam 234. Absorber 250 is configured to absorb a fraction of ions flowing from first plasma 220 to absorber 250 while allowing the non-absorbed ions to pass through towards support structure 208. In particular, absorber 250 is configured such that the ion transparency of absorber 250 varies across absorber 250. Ion transparency is defined as the percentage of ions incident to absorber 250 that are allowed to pass through absorber 250. Thus, regions of absorber 250 having higher ion transparencies allow a higher percentage of ions to pass through compared to regions of absorber 250 having lower ion transparencies. Absorber 250 may be configured to have regions of lower ion transparency and regions of higher ion transparency. In the present example, the regions of lower ion transparency may be positioned in areas of drift region 226 having higher current densities while the regions of higher ion transparency may be positioned in areas of drift region 226 having lower current densities. Thus, absorber 250 may be configured such that the current density profile of ions exiting absorber 250 is more uniform than the current density profile of ions flowing from first plasma 220 to absorber 250. In one example, absorber 250 is configured to have increasing ion transparency from the center to the outer edge of absorber 250.

The support structure 208 disposed with the process chamber 204 is configured to position work piece 206 in the path of ion beam 234 for ions bombard and second plasma 330 for deposition. Work piece 206 may be a semiconductor substrate (e.g., silicon wafer) used in fabricating IC chips or solar cells. In other cases, work piece 206 may be a glass substrate with thin-film semiconductor layers used in fabricating flat panel displays or thin-film solar cells.

In some embodiments, support structure 208 may be configured to rotate or tilt work piece 206 to control the incidence angle of ion beam 234 with respect to the perpendicular of work piece 206. It should be recognized that support structure 208 may be configured to rotate work piece 206 while tilting work piece 206 at a given angle.

In one embodiment of the present invention, the deposition apparatus may not include grids 224. In such case, support structure 208 may be configured to apply a bias voltage on work piece 206. For example, support structure may be coupled to bias power source 254 to apply a bias voltage to work piece 206. Biasing work piece 206 functions to accelerate ions from first plasma 220 towards work piece 206, thereby bombarding work piece 206 with ions.

In one embodiment of the present invention, plasma source chamber 202 includes end wall 216 disposed at one end 217 of plasma source chamber 202 and at least one sidewall 218 defining the interior of plasma source chamber 202 between end wall 216 and opposite end 222 of plasma source chamber 202. In this example, sidewall 218 is cylindrical and has a circular cross-section. However, in other cases, sidewall 218 may have a rectangular cross-section.

As shown in FIG. 1, plasma source chamber 202 has an internal diameter 236. Internal diameter 236 defines the cross-sectional area of plasma source chamber 202 and thus at least partially determines the cross-sectional area of plasma 220 and of ion beam 234. In the present example, internal diameter 236 of plasma source chamber 202 is larger than the diameter of work piece 206. Additionally, the extraction area of grids 224 is larger than the area of work piece 206. Thus, ion beam 234 is generated having a cross-sectional area larger than the area of work piece 206. In one example, internal diameter 236 may be greater than 45 cm. In another example, internal diameter 236 may be between 45 and 60 cm.

Plasma source chamber 202 includes first set of magnets 210 disposed on end wall 216, second set of magnets 212 disposed on sidewall 218, and third set of magnets 214 extending across the interior of chamber 202. Each magnet of third set of magnets 214 may be housed within a protective tube. End wall 216, sidewall 218, and the third set of magnets 214 define plasma generation region 232 within the interior of plasma source chamber 202. In this example, first set of magnets 210, second set of magnets 212, and third set of magnets 214 are configured to confine energetic electrons of plasma 220 within plasma generation region 232. Energetic electrons may be defined as electrons having energy greater than 10 eV. Particularly, third set of magnets 214 is configured to confine a majority of electrons of plasma 220 having energy greater than 10 eV within plasma generation region 232 while allowing ions from plasma 220 to pass through third set of magnets 214 into process chamber 204 for ion bombard of work piece 206.

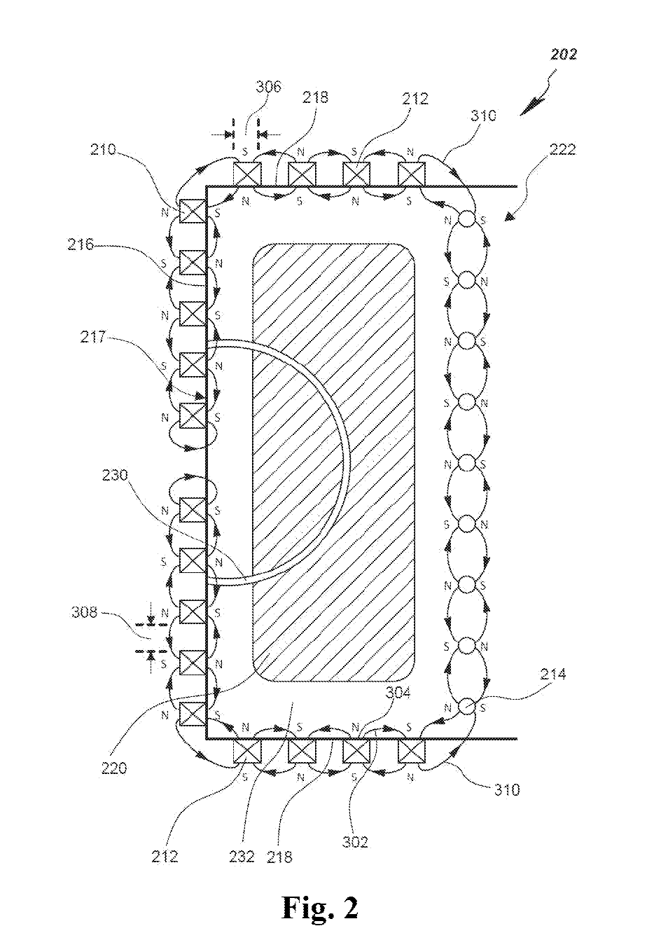

FIG. 2 depicts a cross-sectional view of an exemplary plasma source chamber 202. As shown in FIG. 2, first set of magnets 210, second set of magnets 212, and third set of magnets 214 are arranged with alternating polarities to produce multi-cusp magnetic fields (illustrated by magnetic field lines 302) that surround plasma generation region 232. The multi-cusp magnetic fields confine a majority of energetic electrons of plasma 220 within plasma generation region 232 by repelling the energetic electrons from end wall 216, sidewall 218, and third set of magnets 214. More specifically, the multi-cusp magnetic fields function to reflect energetic electrons of plasma 220 from end wall 216, sidewall 218, and third set of magnet, thereby enabling most energetic electrons to traverse at least several times across the length and/or diameter of plasma generation region 232 before finally being lost to end wall 216 or sidewall 218. By increasing the path length travelled by energetic electrons within plasma generation region 232, the probability of ionizing an atom or molecule increases. Thus, first set of magnets 210, second set of magnets 212, and third set of magnets enable higher ionization rates in plasma 220 compared to the plasmas generated by conventional plasma sources having no magnetic confinement or only partial magnetic confinement.

In the present of first set of magnets 210, second set of magnets 212, and third set of magnets 214, plasma 220 may become stable or sustainable at pressures below 0.1 Pa. Furthermore, the first set of magnets 210 and second set of magnets 212 may comprise ceramic permanent magnets (e.g., ferrite magnets) and are configured such that the magnetic field strength at the inner surfaces of end wall 216 and sidewall 218 is between 0.1 kG and 1 kG.

As shown in FIG. 2, each magnet of first set of magnets 210, second set of magnets 212, and third set of magnets 214 has a width 306. In one example, width 306 is between 2 mm and 15 mm. In another example, width 306 may be between 4 mm and 8 mm. Magnets of first set of magnets 210, second set of magnets 212, and third set of magnets 214 may be evenly spaced apart at spacing 308. In one example, spacing 308 between adjacent magnets is between 2 cm and 15 cm. In another example, spacing 308 is between 4 cm and 8 cm.

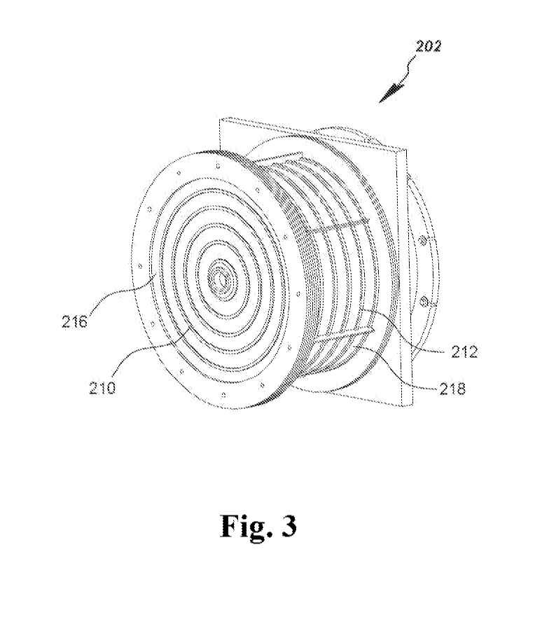

Referring to FIG. 3, first set of magnets 210 may comprises concentric rings of permanent magnets distributed along end wall 216. Second set of magnets 212 may comprises rows of permanent magnets that extend around the circumference of sidewall 218.

The magnets surround the plasma generation region may confine the energetic electrons of the plasma with the plasma generation; furthermore, the magnets may approve the deposition efficiency.

In summary, the deposition of the present invention comprises plasma source chamber and process chamber having first plasma generator and second plasma generator, respectively. Wherein the first plasma generator in the plasma source chamber may generate first plasma with ions and the ions of the first plasma will be extracted and accelerated toward the work piece in the process chamber by the grid to conduct implantation or to assist deposition. In addition, the second plasma generator may generate second plasma with radical using the accessed gas and the ions from plasma source chamber to conduct deposition. As described above, the deposition apparatus of the present invention may conduct different process modes (for example, implantation and deposition) by operate plasma source chamber and process chamber respectively or simultaneously; furthermore, the deposition apparatus of the present invention has excellent deposition efficiency compared to the conventional deposition device.

The embodiments as above only illustrate the technical concepts and characteristics of the present invention; it is purposed for person ordinary skill in the art to understand and implement the present invention, but not for the limitation to claims of the present invention. That is, any equivalent change or modification in accordance with the spirit of the present invention should be covered by the appended claims

What is claimed is:

1. A deposition apparatus, comprising:
a process chamber, wherein a work piece is disposed therein;
a plasma source chamber coupled to the process chamber, the plasma source chamber comprising a first plasma generator for ionizing a first gas in the plasma source chamber to generate a first plasma having ions, the ions of the first plasma bombard the work piece; and
a second plasma generator disposed within the process chamber, the second plasma generator ionized a second gas in the process chamber to generate a second plasma having radical to deposit a surface of the work piece.

2. The deposition apparatus of claim 1, wherein the ions of the first plasma pass through the second plasma generator.

3. The deposition apparatus of claim 1, wherein the process chamber comprises an gas inlet to access a third gas into the process chamber, wherein the second gas comprises the ions of the first plasma and the third gas.

4. The deposition apparatus of claim 3, wherein the third gas comprises atoms to be deposited on the surface of the work piece.

5. The deposition apparatus of claim 3, wherein the first gas and the third gas comprise atoms to be deposited on the surface of the work piece.

6. The deposition apparatus of claim 1, wherein the first plasma generator comprises an antenna or induction coil.

7. The deposition apparatus of claim 1, wherein the second plasma generator comprises an antenna or induction coil.

8. The deposition apparatus of claim 1, further comprising a support structure disposed within the process chamber, the support structure configured to support the work piece and apply a bias voltage to the work piece so as to accelerate the ions of the first plasma to the work piece.

9. The deposition apparatus of claim 1, further comprising a plurality of grids disposed between the first plasma generator and the support structure, wherein the plurality of grids are configured to extract an ion beam comprising the ions from the first plasma and to accelerate the ion beam through the plurality of grids towards the work piece.

10. The deposition apparatus of claim 9, wherein the plurality of grids are configured to focus the ion beam as the ion beam passes through the plurality of grids.

11. The deposition apparatus of claim 9, wherein the plurality of grids control the ion concentration distribution of the ion beam.

12. The deposition apparatus of claim 1, wherein the first plasma chamber comprises:
an end wall disposed at a first end of the plasma source chamber;
at least one sidewall defining a chamber interior between the first end and a second end of the plasma source chamber opposite to the first end;
a first plurality of magnets disposed on the end wall;
a second plurality of magnets disposed on the at least one sidewall and surrounding the chamber interior; and
a third plurality of magnets extending across the chamber interior,
wherein the end wall, the at least one sidewall, and the third plurality of magnets define a plasma generation region within the chamber interior, wherein the plasma source chamber is configured to generate the first plasma having the ions within the plasma generation region.

13. The deposition apparatus of claim 12, wherein the first plurality of magnets, the second plurality of magnets, and the third plurality of magnets are configured to generate a plurality of multi-cusp magnetic fields surrounding the plasma generation region.

14. The deposition apparatus of claim 12, wherein the first plurality of magnets, the second plurality of magnets, and the third plurality of magnets are configured to enable the plasma to be sustained within the plasma generation region at a pressure below 0.1 Pa.

15. The deposition apparatus of claim 12, wherein a magnetic field strength at an inner surface of the end wall and the sidewall is between 0.1 kG and 1 kG.

16. The deposition apparatus of claim 12, wherein the first plurality of magnets and the second plurality of magnets comprise ceramic permanent magnets.

17. The deposition apparatus of claim 12, wherein a width of each magnet of the third plurality of magnets is between 3 mm and 15 mm and a spacing between adjacent magnets of the third plurality of magnets is between 2 cm and 15 cm.

18. The deposition apparatus of claim 12, wherein the third plurality of magnets comprise concentric rings of permanent magnets or linear permanent magnets.

19. The deposition apparatus of claim 12, wherein an internal diameter of the plasma source chamber is greater than 45 cm.

20. A deposition method, comprising the following steps:
positioning a work piece in a process chamber, wherein the process chamber comprise a second plasma generator;
operating a first plasma generator in a plasma source chamber to ionize a first gas in the plasma source chamber and then generate a first plasma having ions, the ions of the first plasma bombard the work piece, wherein the plasma source chamber coupled to the process chamber; and
operating the second plasma generator to ionize a second gas in the process chamber, and then generate a second plasma having radical to deposit a surface of the work piece.

21. The deposition method of claim 20, the step of operating the first plasma generator further comprises passing the ions of the first plasma through the second plasma generator.

22. The deposition method of claim 20, wherein the process chamber comprises an gas inlet to access a third gas into the process chamber, wherein the second gas comprises the ions of the first plasma and the third gas.

23. The deposition method of claim 22, wherein the third gas comprises atoms to be deposited on the surface of the work piece.

24. The deposition method of claim 22, wherein the first gas and the third gas comprise atoms to be deposited on the surface of the work piece.

25. The deposition method of claim 20, wherein the first plasma generator comprises an antenna or induction coil.

26. The deposition method of claim 20, wherein the second plasma generator comprises an antenna or induction coil

27. The deposition method of claim 20, wherein the process chamber comprises a support structure disposed therein, the support structure configured to support the work piece and apply a bias voltage to the work piece so as to accelerate the ions of the first plasma to the work piece.

28. The deposition method of claim 20, further comprising a plurality of grids disposed between the first plasma generator and the support structure, wherein the plurality of grids are configured to extract an ion beam comprising the ions from the first plasma and to accelerate the ion beam through the plurality of grids towards the work piece.

29. The deposition method of claim 28, wherein the plurality of grids are configured to focus the ion beam as the ion beam passes through the plurality of grids.

30. The deposition method of claim 28, wherein the plurality of grids control the ion concentration distribution of the ion beam.

31. The deposition method of claim 20, wherein the first plasma chamber comprises:
an end wall disposed at a first end of the plasma source chamber;
at least one sidewall defining a chamber interior between the first end and a second end of the plasma source chamber opposite to the first end;
a first plurality of magnets disposed on the end wall;
a second plurality of magnets disposed on the at least one sidewall and surrounding the chamber interior; and
a third plurality of magnets extending across the chamber interior,
wherein the end wall, the at least one sidewall, and the third plurality of magnets define a plasma generation region within the chamber interior, wherein the plasma source chamber is configured to generate the first plasma having the ions within the plasma generation region.

32. The deposition method of claim 31, wherein the first plurality of magnets, the second plurality of magnets, and the third plurality of magnets are configured to generate a plurality of multi-cusp magnetic fields surrounding the plasma generation region.

33. The deposition method of claim 31, wherein the first plurality of magnets, the second plurality of magnets, and the third plurality of magnets are configured to enable the plasma to be sustained within the plasma generation region at a pressure below 0.1 Pa.

34. The deposition method of claim 31, wherein a magnetic field strength at an inner surface of the end wall and the sidewall is between 0.1 kG and 1 kG.

35. The deposition method of claim 31, wherein the first plurality of magnets and the second plurality of magnets comprise ceramic permanent magnets.

36. The deposition method of claim 31, wherein a width of each magnet of the third plurality of magnets is between 3 mm and 15 mm and a spacing between adjacent magnets of the third plurality of magnets is between 2 cm and 15 cm.

37. The deposition method of claim 31, wherein the third plurality of magnets comprise concentric rings of permanent magnets or linear permanent magnets.

38. The deposition method of claim 31, wherein an internal diameter of the plasma source chamber is greater than 45 cm.
